(19) United States
(12) Patent Application Publication
(10) Pub. No.: US 2013/0312429 A1
(43) Pub. Date: Nov. 28, 2013

(54) METHOD AND APPARATUS FOR THERMOACOUSTIC COOLING

(71) Applicants: Jean-Baptiste Greuet, Ulm (DE); Lars Cieslak, Ulm (DE)

(72) Inventors: Jean-Baptiste Greuet, Ulm (DE); Lars Cieslak, Ulm (DE)

(73) Assignee: Noki Corporation, Espoo (FI)

(21) Appl. No.: 13/983,843

(22) PCT Filed: Feb. 25, 2011
(86) PCT No.: PCT/IB2011/050816

§ 371 Date: Aug. 6, 2013

(51) Int. Cl. H05K 7/20

(52) U.S. Cl. CPC H05K 7/20
USPC 62/6

(57) ABSTRACT

Apparatus comprising at least one transducer comprising a displacement component that is configured to move upon application of an electrical signal; a cavity in communication with the at least one transducer; and at least one thermodynamic member within the cavity configured to readily exchange heat with a cavity gas or fluid, wherein the transducer is configured to generate a standing wave within the cavity to transfer heat along the thermodynamic member.

### FIELD OF THE APPLICATION

The present invention relates to thermoacoustic cooling apparatus. The invention further relates to, but is not limited to, thermoacoustic cooling apparatus for mobile devices.

### BACKGROUND OF THE APPLICATION

Electronic components in real world applications generate heat when in operation. For example components can have resistive losses such as found in coils in transducers and transistors have transistor switching losses where electrical energy is converted into heat during every switch state change. These switching losses are particularly substantive in modern integrated circuit processors where the clocking frequencies are high.

Typical heat generators in mobile devices can be, for example the radio frequency engine (in other words the radio frequency transceiver components), the baseband engine (in other words the processors controlling the coding and decoding of the data signals, such as the audio data), transducers (such as the speaker), and display elements (such as the mini projector light generator) require to be cooled if they are not to reach a damaging temperature.

Component density levels have been sufficiently low and/or switching frequencies low enough to allow thermal dissipation of heat from electrical components (such as integrated circuits) to dissipate heat from “hot spots” sufficiently without reaching a thermal limit for the device.

For example passive heat dissipation in mobile devices such as phones can use expensive heat spreader tapes which attempt to conduct heat from the heat generator, or where there is sufficient volume heat pipes which carry out a similar conductive process of heat away from the potential hot spot but which require a significant volume for a small device. Furthermore in some situations, phase changing materials can be used to temporarily absorb heat by going through a phase change. However these are expensive and cannot be used without some circulatory system to recycle the heat.

Where component density or switching frequencies are higher, for example such as in central processing units (CPU) or Digital Signal Processing (DSP), active cooling has been implemented to prevent devices reaching their thermal limit. Active cooling can, for example be implemented by the use of fans which blow a stream of air onto the surface of the component producing a greater thermal differential at the surface of the component and thus allow more heat energy to be dissipated. Whilst the use of fans in desktop or large equipment is acceptable, the use of fans in mobile devices is problematic in that they typically require a relatively large volume, can be acoustically noisy, and can be prone to failure causing the device to pass the thermal limit and fail. Furthermore forced air cooling requires an inlet and outlet in the device to be maintained for efficient flow of cooler air and removal of warmer air. These inlets and outlets can allow the ingress of foreign material such as metallic particles which can damage sensitive electromechanical components such as the speaker transducer.

Where the component density is even higher or frequencies suitably high even forced air cooling may not be sufficient and cooled liquid or water cooling can be used. However liquid cooling further has inherent disadvantages when used in electronic apparatus in that it is typically heavy, requires ever more volume to implement, and can cause water vapour to condense on electronic components causing them to fail.

For these reasons, forced air and water cooled systems are typically not implemented in portable devices and mobile devices but used in larger devices such as desktop computers.

### SUMMARY OF SOME EMBODIMENTS

Embodiments of the present invention attempt to overcome heating issues by implementing thermoacoustic cooling apparatus within electronic devices.

There is provided according to an aspect of the application an apparatus comprising: at least one transducer comprising a displacement component that is configured to move upon application of an electrical signal; a cavity in communication with the at least one transducer; and at least one thermodynamic member within the cavity configured to readily exchange heat with a cavity gas or fluid, wherein the transducer is configured to generate a standing wave within the cavity to transfer heat along the thermodynamic member.

The thermodynamic member may comprise a substrate.

The substrate may comprise at least one of: at least two layers of thermodynamic material; and at least two tubes of the thermodynamic material.

The cavity may be substantially sealed at least at one end.

The apparatus may further comprise a heat sink configured to be coupled to a first end of the at least one thermodynamic member.

The heat sink may comprise at least one of: a cover region of the apparatus; and a battery of the apparatus.

The apparatus may further comprise a first heat conductor coupling the first end of the at least one thermodynamic member to the heat sink at a higher pressure region of the cavity.

The apparatus may further comprise a heat source configured to be coupled to a second end of the at least one thermodynamic member.

The heat source may comprise at least one of: a processor; a radio frequency engine; a baseband engine; and a projector light source.

The apparatus may further comprise a second heat conductor coupling the second end of the at least one thermodynamic member of the heat source at a lower pressure region of the cavity.

The cavity may be a resonator.

A first transducer may be located at one end of the resonator and the opposite end of the resonator may be sealed.

A first transducer may be located at one end of the resonator and a second transducer may be located at the opposite end of the resonator.

The at least one member may be a material comprising a high heat capacity and a low thermal conductivity.

The cavity standing wave may resonate at a frequency outside of the hearing threshold.

The transducer may be further configured to generate an acoustic wave at an audible frequency.

The cavity standing wave may resonate at an audible frequency.

According to a second aspect there is a method comprising: controlling at least one transducer comprising a displacement component to move upon application of an electrical signal; coupling a cavity with the at least one transducer; and locating at least one thermodynamic member within the cavity, wherein the at least one thermodymamic member exchanges heat with a cavity gas or fluid; wherein controlling the at least one transducer generates a standing wave within the cavity and transfers heat along the thermodynamic member.

The method may further comprise substantially sealing the cavity at at least one end.

The method may further comprise coupling a first heat conductor to a first end of the at least one thermodynamic member at a higher pressure region of the cavity.

The method may further comprise coupling a heat source to a second end of the at least one thermodynamic member.

The heat source may comprise at least one of: a processor; a radio frequency engine; a baseband engine; and a projector light source.

Coupling a heat source to a second end of the at least one thermodynamic member further may comprise coupling a second heat conductor to the second end of the at least one thermodynamic member of the heat source at a lower pressure region of the cavity.

Generating a standing wave within the cavity may comprise generating the cavity standing wave at a frequency outside of the hearing threshold.

Controlling at least one transducer comprising a displacement component to move upon application of an electrical signal may comprise controlling the transducer to generate an acoustic wave at an audible frequency.

According to a third aspect there is provided apparatus comprising: transducer means for moving a gas upon application of an electrical signal; means for generating a cavity in communication with the at least one transducer; and means for readily exchanging heat with a cavity gas or fluid, wherein the transducer means generate a standing wave within the cavity to transfer heat along the means for readily exchanging heat.

An electronic device may comprise apparatus as described above. Embodiments of the present application aim to address the above problems.

### BRIEF DESCRIPTION OF DRAWINGS

For better understanding of the present application, reference will now be made by way of example to the accompanying drawings in which:

FIG. 1 shows schematically an apparatus suitable for employing some embodiments of the application;

FIG. 2 shows schematically on overview of a thermoacoustic cooling module according to some embodiments;

FIG. 3 shows schematically a three dimensional view of a practical implementation of a thermoacoustic cooling module;

FIG. 4 shows schematically a half wavelength standing wave implementation model of a thermoacoustic cooling module;

FIG. 5 shows schematically a half wavelength standing wave thermoacoustic cooling module implemented in an integrated hands free module;

FIG. 6 shows schematically a further half wavelength standing wave thermoacoustic cooling module implemented in a speaker module.

FIGS. 7a, 7b and 7c shows schematically a quarter wavelength standing wave implementation model of a thermoacoustic cooling module;

FIG. 8 shows schematically a half and quarter wavelength standing wave thermoacoustic cooling module implemented in a speaker module;

FIG. 9 shows an example of the integration of a thermoacoustic cooling module according to some embodiments implemented within a mobile device; and

FIG. 10 shows a flow chart of the operation of the thermoacoustic cooling module.

### SOME EMBODIMENTS OF THE APPLICATION

The following describes in further detail suitable apparatus and possible mechanisms for the provision of thermoacoustic cooling in devices equipped with speakers or other transducers.

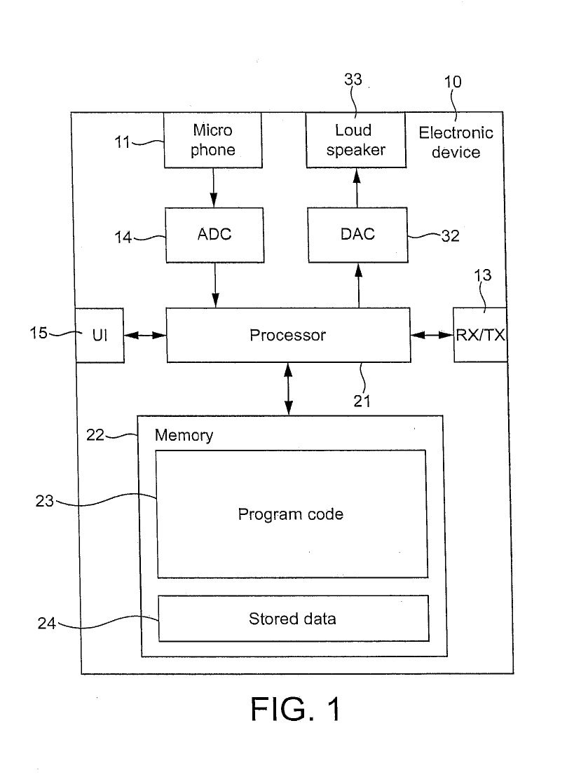

With respect to FIG. 1 a schematic diagram of an exemplary apparatus or electronic device 10 which may implement a thermoacoustic cooling module according to some embodiments of the application is shown. The apparatus 10 can in some embodiments be a mobile terminal or user equipment of a wireless communication system. In other embodiments the apparatus 10 can be any electronic device. For example in some embodiments the electronic device or apparatus 10 can be an audio player (also known as MP3 player), a media player (also known as MP4 player), a personal computer, laptop or any device generating localised hot spots, heat generators which require cooling, or any suitable regions which require cooling in order to perform correctly or more accurately (for example portable infra-red sensors requiring a cooled detector).

The electronic device 10 in some embodiments comprises at least one microphone 11, which is connected via an analogue-to-digital converter (ADC) 14 to a processor 21. The processor 21 is further linked via a digital-to-analogue converter (DAC) 32 at least one speaker 33. The processor 21 is in some further embodiments further connected or linked to a transceiver (RX/TX) 13, and also to a user interface (UI) 15 and to a memory 22.

The processor 21 can in some embodiments be configured to execute various program codes. The implemented program code can in some embodiments comprise code as described herein for controlling cooling operations. The implemented program codes can in some embodiments be stored, for example, within the memory 22 and specifically within a program code section 23 of the memory 22 for retrieval by the processor 21 whenever needed. The memory 22 can in some further embodiments provide a data storage section 24, for example for storing data which has been processed in accordance with embodiments of the application, and/or storing data prior to processing according to embodiments of the application.

The code can in some embodiments of the application be implemented at least partially in hardware or firmware where specified hardware is provided to carry out the operations disclosed hereafter.

The user interface 15 enables a user to input commands to the apparatus 10, for example via a keypad, and/or to obtain information from the apparatus 10 for example via a display. It would be understood that in some embodiments the operations of input of data and display of data can be implemented by a touch screen display.

The transceiver 13 can be configured in some embodiments to enable communication with other devices, for example via a wireless communications network.

It is to be understood that the structure of the apparatus 10 could be supplemented and varied in many ways and only schematically represents the components or features which are directly concerned with some embodiments of the application.

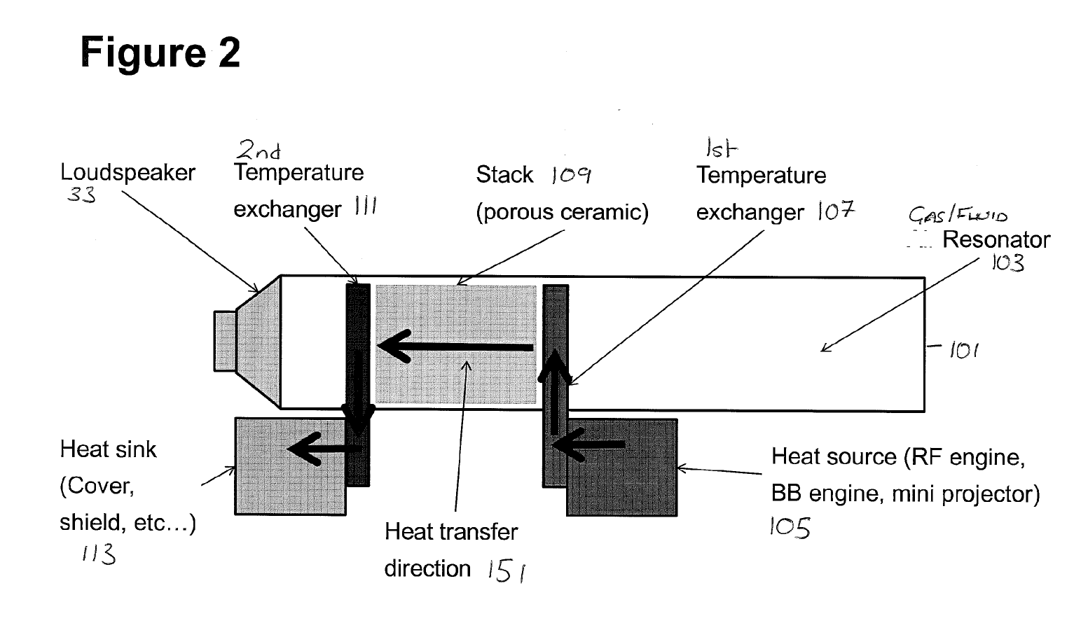

With respect to FIG. 2, an example implementation of a thermoacoustic cooler apparatus implementable within embodiments of the application is shown. The cooler apparatus comprises at least one loudspeaker 33. The at least one loudspeaker 33 can be any suitable audio or acoustic transducer. In some embodiments the loudspeaker 33 can be configured to generate acoustic frequencies above the human hearing range as well as within conventional human hearing range. The at least one loudspeaker 33 is configured to be coupled to and generate a resonant or standing wave within a resonator chamber 101 acoustic chamber within which is filled air 103. It would be understood that in some other embodiments any other suitable gas or gaseous mixture could be employed. For example in some embodiments the acoustic chamber 101 can be filled with helium. Furthermore in some embodiments the acoustic chamber 101 can be filled with any suitable fluid permitting a standing wave to be generated within it.

In some embodiments the cooler apparatus comprises a resonator chamber 101 or acoustic chamber. The resonant chamber 101 in some embodiments is any suitable acoustically reflective material. Furthermore in some embodiments, the resonator chamber 101 can be configured or tuned in such a way that the main resonant frequency occurs above the hearing threshold of the human ear making the operation of the chamber inaudible to the human ear. In such a way it can be possible for the loudspeaker 33 to be generating a suitable high sound pressure level volume to generate the resonance for carrying out thermoacoustic cooling at a first frequency whilst also generating normal speech or music signals to be heard by the user.

The cooler apparatus further in some embodiments comprises within the resonator chamber 101 a first temperature exchanger 107 which is coupled to a heat source 105. Coupling as described herein can be achieved in some embodiments by a direct coupling, or connection whereby the parts coupled are touching. Furthermore in some embodiments the term coupling can be understood as an indirect coupling whereby a further part enables the transfer of energy from one part to another. For example an indirect coupling between a first material and a second material can be a gas which conducts heat from one material to another and an example of a direct coupling is where the two materials are touching and establish a thermal connection.

The cooler apparatus in some embodiments comprises a heat source 105. The heat source 105 can represent, for example, a processor, a radio frequency engine, a base band engine, a mini-projector module, or any suitable heat generating component or equipment that requires cooling. In some embodiments the hot temperature heat exchanger 107 is coupled not to a heat source or generator but to a device to be cooled, such as an infrared sensor device. The first heat exchanger 107 in such embodiments is located at least partially within the resonator chamber 101 and is further coupled to a stack 109 or thermodynamic member.

In embodiments the cooling apparatus further comprises a stack 109 or thermodynamic member. The stack 109 is in some embodiments can be formed by a porous ceramic material, in other words a material containing holes through which the audio waves or acoustic waves can pass air, however the stack 109 can in some further embodiments comprise a pile of regularly or irregularly spaced ceramic, or plastic, or other heat transfer material tubes where the material has a higher heat capacity than the surrounding gas and a sufficient low thermal conductivity.

Furthermore in some embodiments the stack 109 comprises a series of layers of the material spaced from each other by a spacer.

In order to perform correctly the distance between two layers of stack material are optimised in order to facilitate both the heat exchange between the fluid and the solid materials and the sound circulation necessary to maintain standing waves. This distance can be represented by twice the distance of the thermal penetration of the gas (or fluid) δ where:

δ=sqrt(2λ/(ρCω))

Furthermore another parameter to take into account is the critical temperature gradient GradTc, defined as:

GradTc=p/ρCξ

This gradient defines the limit between a system working as a fridge (heat pump), or as a motor (amplifying the sound waves). The critical temperature gradient to be used would be dependent on several variables such as the plastic properties, sound frequency and pressure used.

Where

λ is the thermal conductivity (in W·m⁻¹·K⁻¹)

ρ is the density (in kg·m⁻³)

C is the thermal capacity (in J·kg⁻¹·K⁻¹) ω=2*π*f is the pulsation (f is the frequency of the periodic heat wave)

p is the fluid local overpressure due to standing waves

ξ is the fluid particle displacement

In some embodiments more parameters are taken into account, such as the length, the position within the resonant cavity and material of both the stack material and heat exchangers.

The distance between neighbouring layers of material can further apply to the size of holes in a tubular arrangement of material. The effect of the standing waves and their pressure differences cause the gas to compress and expand in the chamber 101 which transports the heat from the hot temperature heat exchanger 107 towards a cold temperature heat exchanger 111 in a “bucket chain” operation. The direction of heat transfer is shown in FIG. 2 by the heat transfer direction arrows 151.

The cooling apparatus further can comprise in some embodiments a second heat exchanger plate 111. The second heat exchanger 111 can in some embodiments coupled to the side of the stack 109 opposite the first heat exchanger 107. The second heat exchanger 111 furthermore can in such embodiments at least partially be located within the resonator chamber 101. The second heat exchanger 101 is in some embodiments further coupled to a heat sink.

In some embodiments the cooling apparatus further comprises a heat sink 113. The heat sink 113 in some embodiments is created from the cover or part of the casing of the apparatus. For example the heat sink can be an aluminium casing of the back of the apparatus. In some embodiments the heat sink 113 is coupled directly to the stack and the second heat exchanger is optional.

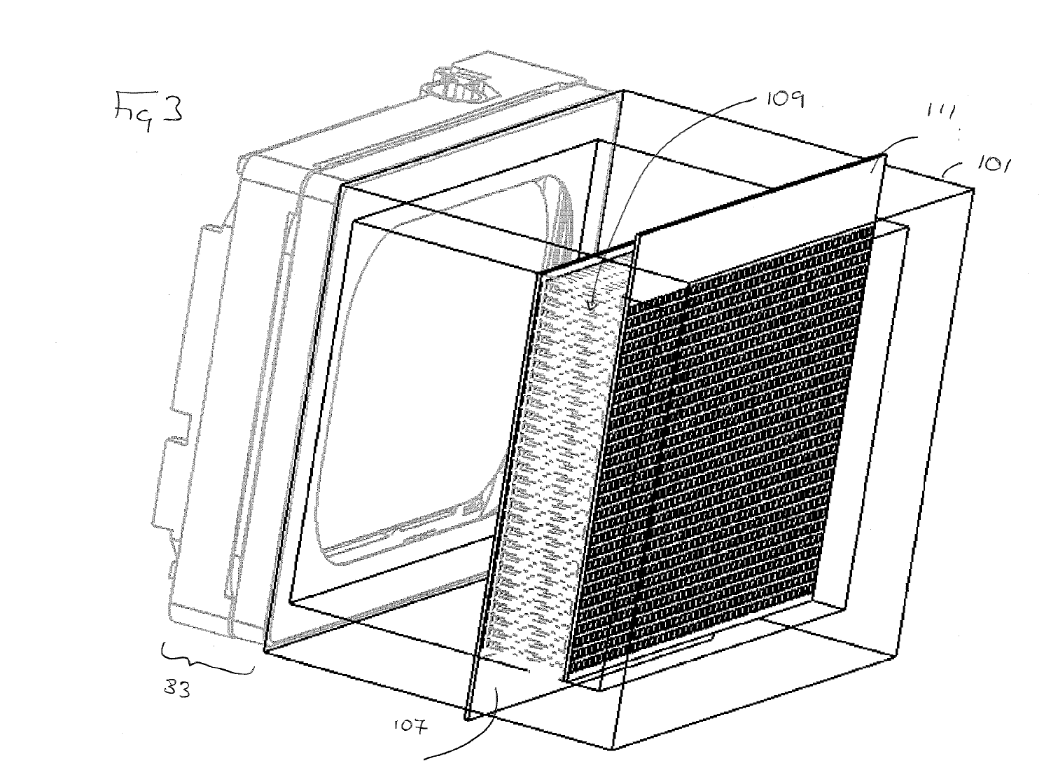

With respect to FIG. 3 a three dimensional view of an example thermoacoustic cooling apparatus is shown. The speaker 33 can be seen coupled to the resonator chamber 101. Furthermore within the resonator chamber 101 can be seen the stack 109 which is shown as an array of layers of material or similar shapes with a first open end of the stack layers coupled to the first heat exchanger 107 and an opposite open end of the stack layers coupled to the second heat exchanger 111. Both the first heat exchanger 107 and the second heat exchanger 111 can in some embodiments be configured to be plates of material with acoustic windows through which the acoustic waves can pass. These acoustic windows can be slots, holes or any suitable shape. The operation of the thermoacoustic cooling apparatus is such that the resonator chamber 101 is designed or configured such that the transducer or speaker 33 can create acoustic standing waves of a specific frequency. Within the resonator chamber operating in a half wavelength resonant frequency mode then closer to the centre of the resonator chamber is located the first heat exchanger 107 and closer to the edge of the resonant chamber 101 is located the second heat exchanger 111.

The first and second heat exchangers 107, 111 can be formed from any suitable efficient heat conductor, such as copper aluminium or other metal.

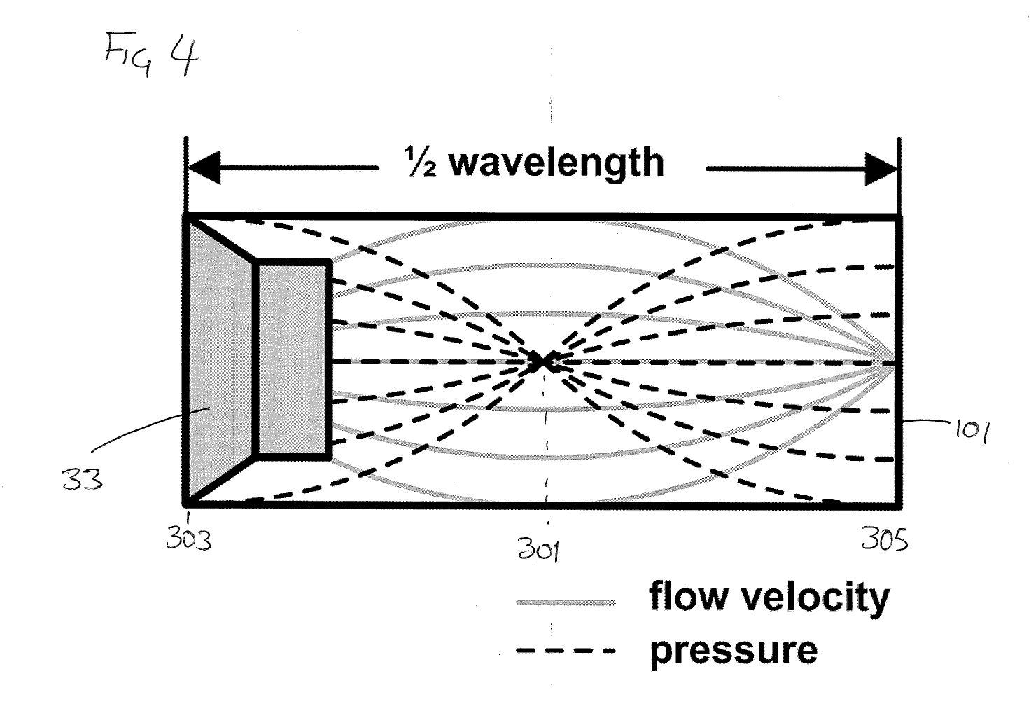

With respect to FIG. 4 a model of a half wavelength resonator chamber 101 is shown. In this example the loudspeaker 33 is configured to generate a standing wave within the acoustic chamber 101 with a half wavelength frequency. In other words the standing wave generated by the single loudspeaker 33 causes the pressure to be at maximum greatest at either end of the resonator chamber 101 but where the flow velocity is greatest or at maximum at the centre of the acoustic resonator chamber 101. The maximum pressure generated at both ends of the resonant chamber is shown in FIG. 4 by the high pressure nodes 303 and 305 and the minimum pressure at a low pressure node 301 at the centre. In such embodiments the thermoacoustic cooling effect can be experienced as a movement of heat energy from near the centre to an associated end of the resonator chamber.

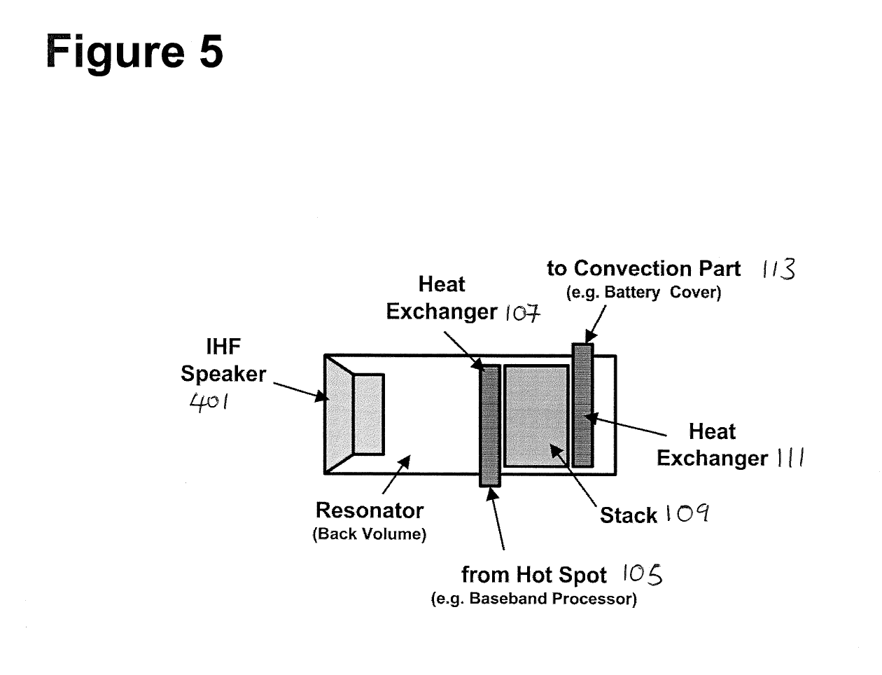

An example embodiment using an integrated handsfree speaker as the speaker 33 using a half wavelength frequency mode is shown in FIG. 5. As shown in FIG. 5 the first heat exchanger 107 is located towards or neighbouring the centre of the resonator chamber 101, the stack 109, which is indirectly coupled via the gas or fluid to the first heat exchanger 107 at one end of the stack and indirectly coupled via the gas or fluid to the second heat exchanger 111 at the other end of the stack towards the far end of the resonator chamber 101. The second heat exchanger 111 can then be coupled to the convection part which can, for example, be a battery cover manufactured from a metallic substance such as aluminium. The integrated handsfree speaker 401 can in some embodiments be located at an open end of the resonator chamber 101, in other words the speaker when located ‘closes’ the ‘open’ end of the resonator chamber 101. The handsfree speaker 401 can therefore enable the thermoacoustic cooling effect by outputting an acoustic signal which generates a half wavelength standing wave. Furthermore in some embodiments the handsfree speaker 401 can output music or speech acoustic signals at a different frequency.

The resonator chamber 101 can thus also be considered to act as or be used as an acoustic back volume for the integrated handsfree loudspeaker 401 to allow a more natural sounding speaker output tuned to produce better audio output. A typical volume for a back volume is about 1 cubic centimetre which can be implemented as part of such a structure as described herein however it would be understood that this value for a back volume is an example value and the back volume can be greater or less than 1 cubic centimetre in some other embodiments.

In some embodiments the resonator chamber 101 can be coupled to more than one loudspeaker. For example, in some embodiments, a loudspeaker module can be mounted at either end of the resonator chamber 101. In other words a loudspeaker or transducer replacing the ‘closed’ or sealed end of the resonator chamber 101 shown in FIG. 5. In such embodiments at least one speaker can be used to generate the acoustic audio signal to be heard by the user whilst the same speaker in combination with the second speaker generates the standing wave in the resonator chamber which in turn is configured to generate the thermoacoustic cooling engine effect. In some embodiments where speakers are arranged at either end of the resonator chamber 101, the sound pressure level and thus the cooling effect can be further increased over the use of a single speaker.

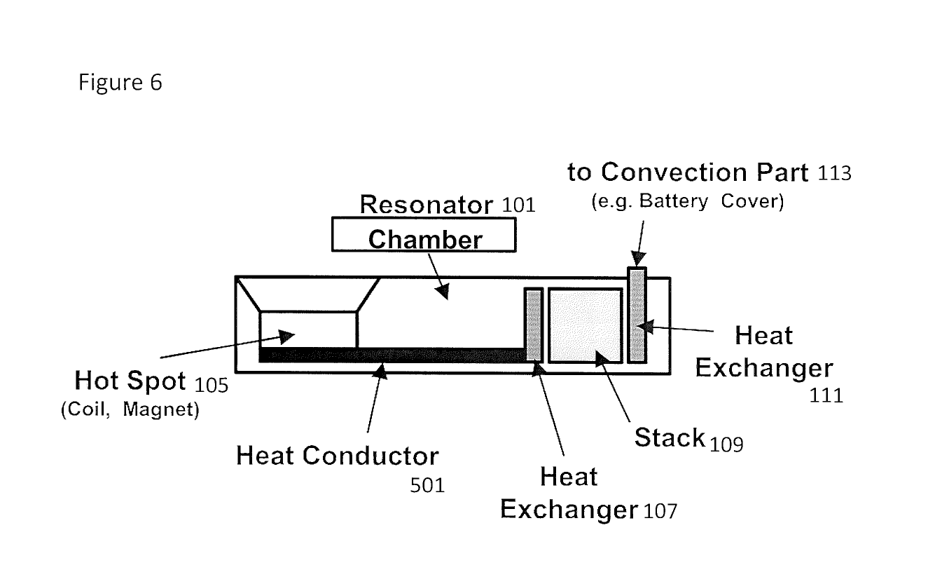

With respect to FIG. 6, a further example of a thermoacoustic cooling module implemented in embodiments of the application is further shown. In the example shown in FIG. 6, the component to be cooled is the transducer, for example the heat generated by the coil or magnet in the transducer. As indicated herein the transducer is typically located at one end of the resonator chamber 101/back volume which does not readily allow thermoacoustic cooling to occur as the cooling or heat transfer in a half wavelength cooling mode occurs from the centre to the end of the chamber. In such embodiments the first heat exchanger 107 located near the centre of the resonator chamber 101 is coupled via a heat conductor 501 to the transducer (hot spot 105 or heat source). Furthermore at the other end of the stack 109 to the opposite end of the resonator chamber 101 to the hot spot (transducer) 105 is the second heat exchanger 111. In such embodiments, the heat conductor 501 can thus be configured to pass the heat generated from the speaker coil and magnet to the first heat exchanger 107 which then using the thermoacoustic cooling effect generated by the combination of the acoustic wave over the stack 109 can efficiently transfer the heat from the first heat exchanger 107 to the second heat exchanger 111 and further to a convection part 113 in the same way as described herein in the half wavelength mode of cooling.

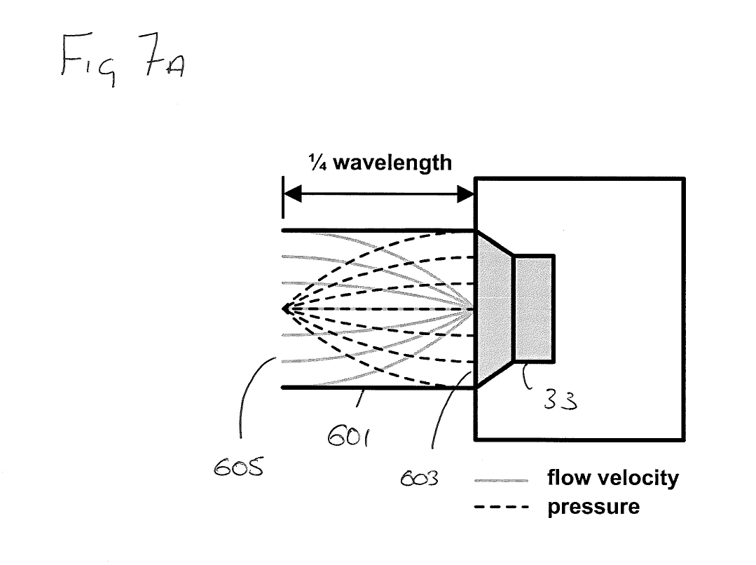

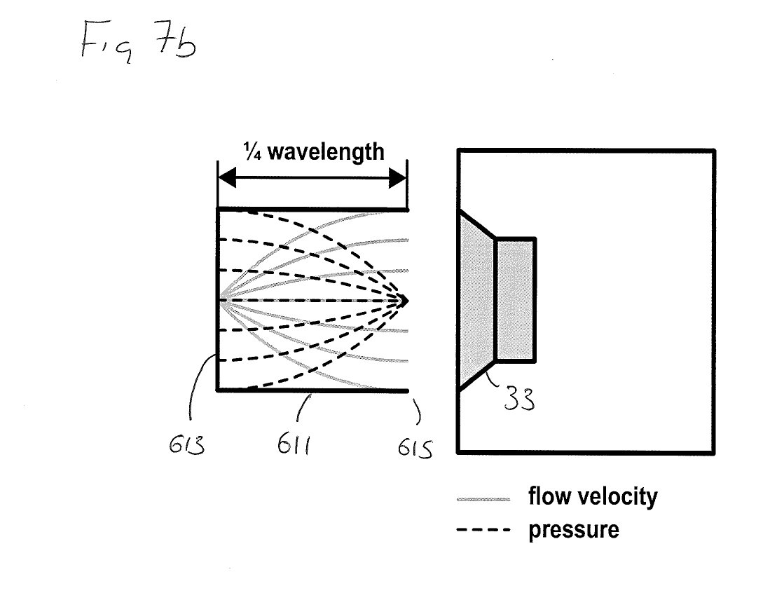

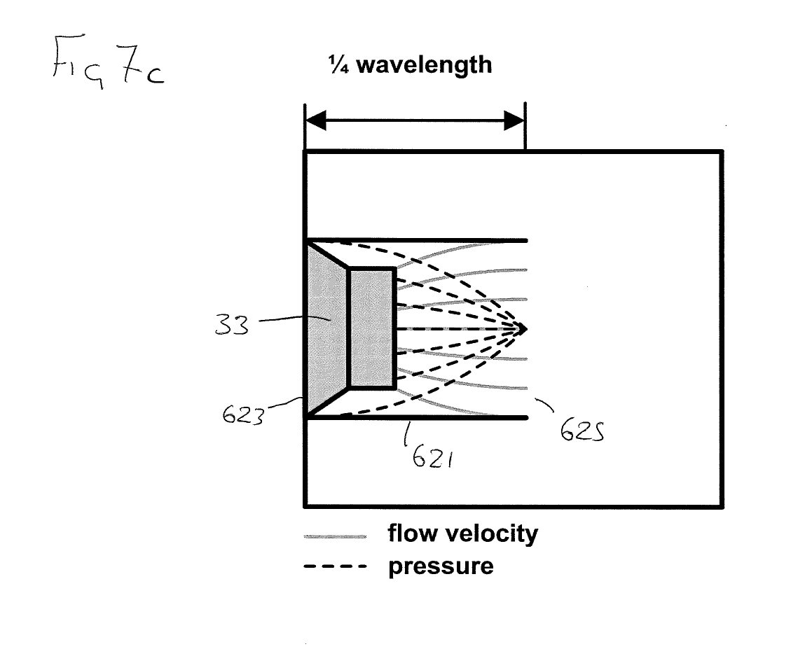

With respect to FIGS. 7a, 7b and 7c, examples of quarter wavelength resonator chamber modes of thermoacoustic cooling are shown. In all three of the examples shown the quarter wavelength resonator chamber 101 has a length which is a quarter of the wavelength of a standing wave.

In the first example shown in FIG. 7a the quarter wave resonator chamber 601 is configured with a first end 603 sealed or closed by the speaker 33 or transducer and the other end 605 open. The frequency of the acoustic wave and the length of the resonator chamber is such that a standing wave is formed with a low flow velocity and high pressure at the first end 603 sealed by the speaker 33 and with a high flow velocity and low pressure at the other end 605. In such embodiments the transfer of heat energy can be shown to occur from the area of minimum pressure (near, but within the resonator, the open or other end 605) to the area of maximum pressure (at the first end 603 which has been closed or sealed by the speaker 33).

In a further example as shown in FIG. 7b a further quarter wave resonator chamber 611 is shown configured with a first end 613 which is sealed and a second end 615 located neighbouring the speaker 33 but open and not sealed by the speaker 33. In such embodiments the frequency of the acoustic wave and the length of the resonator chamber is such that a standing wave is formed with a low flow velocity and high pressure at the first end 613 sealed by the wall of the resonator chamber 611 and with a high flow velocity and low pressure at the second open end 615 neighbouring the speaker 33. In such embodiments the transfer of heat energy can be shown to occur from the area of minimum pressure (at the open or second end 615) to the area of maximum pressure (at the first or chamber closed end 613).

In some embodiments the resonator chamber can be implemented within a back volume of the transducer as shown in the example FIG. 7c. The quarter wave resonator chamber 621 in such embodiments is located within the back volume of the transducer or speaker 33 where a first end 623 which is sealed by the back volume chamber and speaker 33 and a second end 625 which is open and opens out to the back volume chamber. In such embodiments the frequency of the acoustic wave and the length of the resonator chamber is such that a standing wave is formed with a low flow velocity and high pressure at the first end 623 sealed by the wall of the back volume and/or speaker 33 and with a high flow velocity and low pressure region at the second or open end 625. In such embodiments the transfer of heat energy can be shown to occur from the area of minimum pressure (at the open or second end 625) to the area of maximum pressure (at the first or closed end 623).

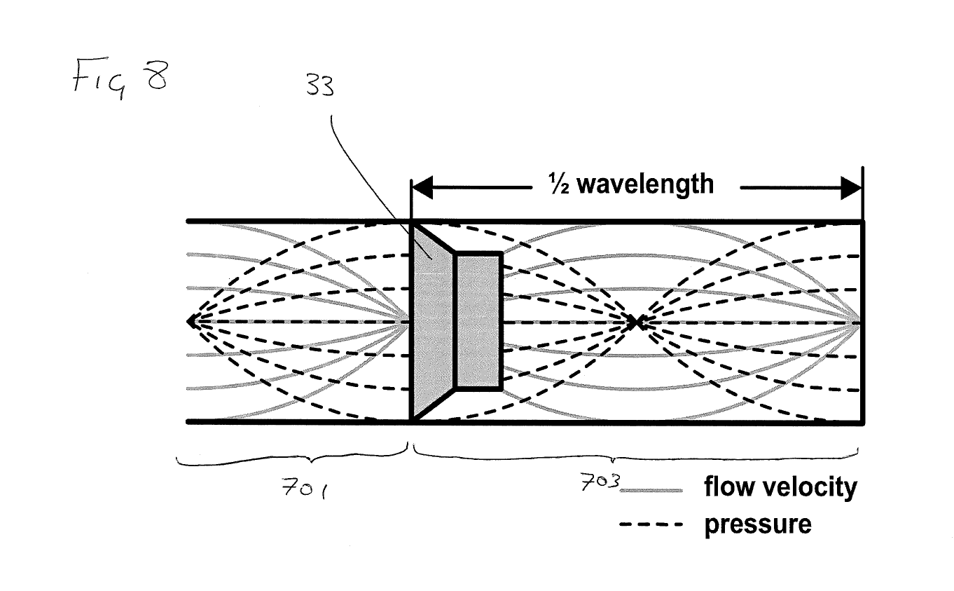

With respect to FIG. 8 a model of apparatus employing two resonator chambers is shown. In the example shown a transducer 33 can generate a first standing wave in a quarter wavelength resonator chamber 701, which is similar to the resonator chamber shown in FIG. 7a. Furthermore the transducer 33 can generate a second standing wave in a half wavelength resonator chamber 703, which is shown similar to the resonator shown in FIG. 4.

The frequency of the acoustic wave and the length of the quarter wavelength resonator chamber 701 is such that the quarter wavelength resonator chamber standing wave is formed with a low flow velocity and high pressure at the first end sealed by the speaker 33 and with a high flow velocity and low pressure at the other or open end. In such embodiments the transfer of heat energy can be shown to occur from the area of minimum pressure (near, but within the resonator, the open or other end) to the area of maximum pressure (at the first end which has been closed or sealed by the speaker 33).

The standing wave generated by the single loudspeaker 33 in the half wavelength resonator chamber 703 causes the pressure to be at maximum greatest at either end of the half wavelength resonator chamber 703 but where the flow velocity is greatest or at maximum at the centre of the half wavelength resonator chamber 703. In such embodiments the thermoacoustic cooling effect experienced in the half wavelength resonator chamber 703 can be experienced as a movement of heat energy from near the centre to an associated end of the half wavelength resonator chamber.

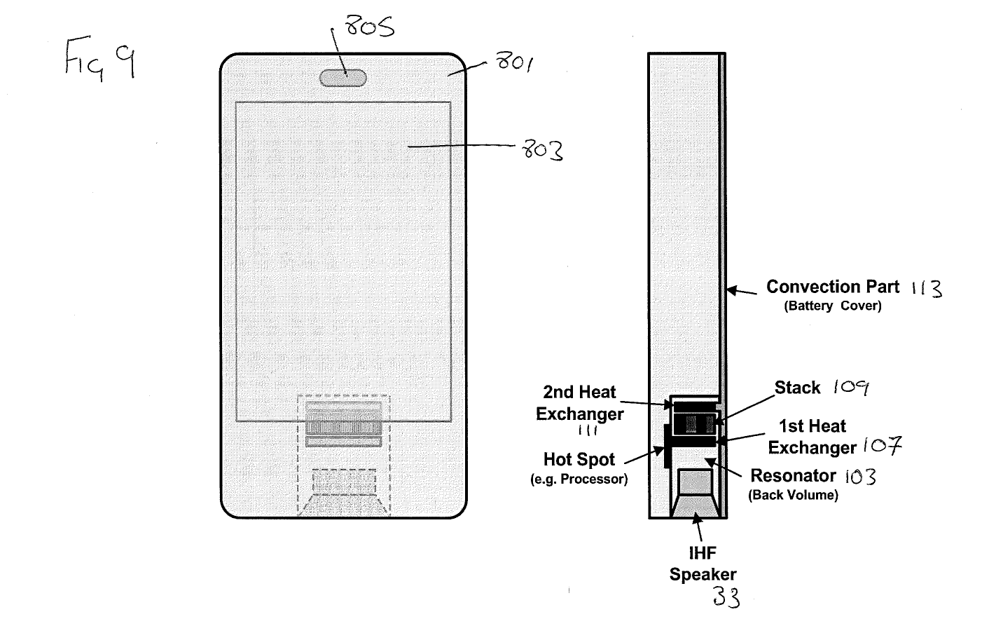

With respect to FIG. 9 a possible implementation arrangement is shown for a thermoacoustic cooling apparatus with respect to the form factor of a typical mobile phone or user equipment. The user equipment has a case 801 which surrounds the sensitive electronic equipment within the case and further surrounds and locates a display element 803, an ear piece hole 805. Furthermore the case 801 has a battery or rear cover which can, for example, be manufactured from a metallic blank such as aluminium blank and is suitable for assisting the transfer or dissipation of heat. The battery cover 811 is coupled to the second heat exchanger 111 within the resonator chamber or back volume defined by the acoustic resonator chamber 101. The second heat exchanger 111 is further coupled to the stack 109 which at the other end of the stack is further coupled to a first heat exchanger 107. The first heat exchanger can then be coupled to a hot spot suitable for cooling such as for example a processor. Furthermore the acoustic chamber 101 has at an end closed by the speaker or transducer which in this example is an integrated handsfree speaker 33. The integrated handsfree speaker 33 can thus generate a suitable standing wave to power the thermoacoustic cooling engine and also provide a suitable audio output for the user.

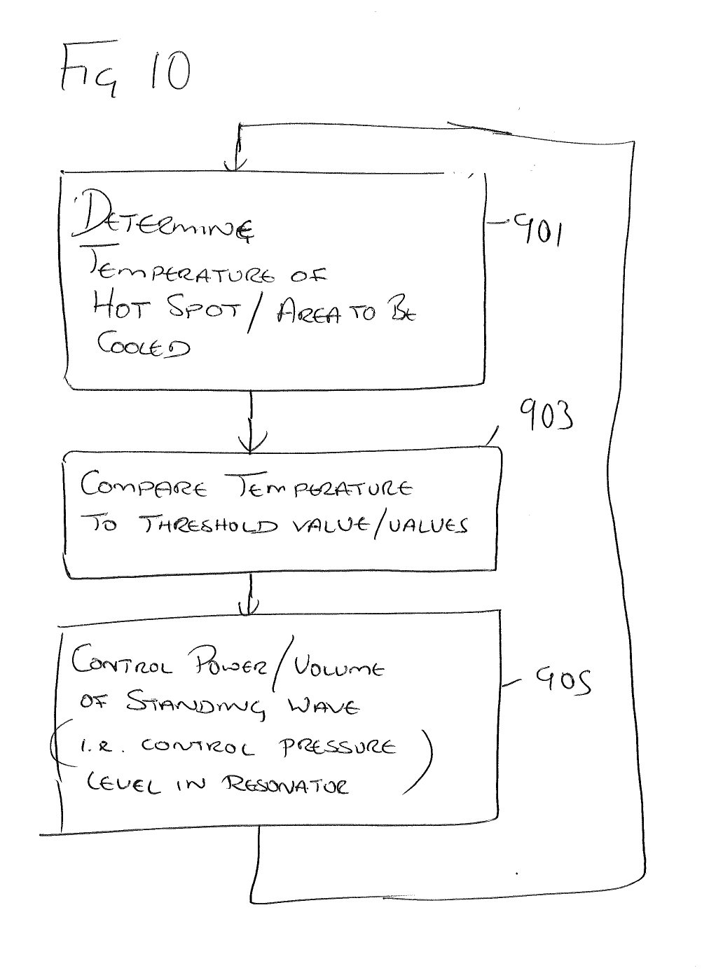

With respect to FIG. 10 the operation of controlling the thermoacoustic cooling apparatus can be shown. In some embodiments, for example, the hot spot which can, for example be a processor, can be furthermore monitored by use of a sensor which determines the temperature of the hot spot.

The determination of the temperature of the hot spot can be shown in FIG. 10 by step 901.

The temperature determined furthermore can be passed to a comparator. The comparator can compare the temperature against a threshold temperature value or values. The threshold value or values can in some embodiments be dynamic or be statically determined. In some embodiments the threshold value can also be stored in memory on the device. The output of the comparator can be passed to a control mechanism. The operation of comparing the temperature against a threshold value or values is shown in FIG. 10 by step 903.

The apparatus can comprise control means for controlling the operation of the transducer 33. The control means can control the power or volume of the standing wave generated by the speaker 33. In such a manner it is possible to increase the sound pressure level or volume of the standing wave to increase the cooling effect where the temperature of the hot spot increases and decrease the sound pressure level of the resonance where the temperature is lower.

The advantages of such an approach is that is requires significantly less expensive heat spreading tape and effectively reuses the existing component of the acoustic back chamber in the mobile device. It is capable of generating no audible or sensible signal can be tuned to the required need of the cooling produces no additional moving parts.

An example system with two speakers could, for example, with a speaker input power of approximately 700 milliwatts each and a tube length approximately 6 centimeters and a stack length of 8 millimeters, where the stack material is a simple Mylar™ stack of material produce a 10.5 degree temperature difference between the hot and the cold sides after only using 3 minutes.

In some embodiments the directionality of the heat exchanger is such that the hot spot should be located below the first temperature heat exchanger, in order to more efficiently transfer the heat as warmer gasses are typically less dense than the same but colder gas.

It shall be appreciated that the term user equipment is intended to cover any suitable type of wireless user equipment, such as mobile telephones, portable data processing devices or portable web browsers.

Furthermore elements of a public land mobile network (PLMN) may also comprise apparatus as described above.

In general, the various embodiments of the invention may be implemented in hardware or special purpose circuits, software, logic or any combination thereof. For example, some aspects may be implemented in hardware, while other aspects may be implemented in firmware or software which may be executed by a controller, microprocessor or other computing device, although the invention is not limited thereto. While various aspects of the invention may be illustrated and described as block diagrams, flow charts, or using some other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof.

The embodiments of this invention may be implemented by computer software executable by a data processor of the mobile device, such as in the processor entity, or by hardware, or by a combination of software and hardware. Further in this regard it should be noted that any blocks of the logic flow as in the Figures may represent program steps, or interconnected logic circuits, blocks and functions, or a combination of program steps and logic circuits, blocks and functions. The software may be stored on such physical media as memory chips, or memory blocks implemented within the processor, magnetic media such as hard disk or floppy disks, and optical media such as for example DVD and the data variants thereof, CD.

The memory may be of any type suitable to the local technical environment and may be implemented using any suitable data storage technology, such as semiconductor-based memory devices, magnetic memory devices and systems, optical memory devices and systems, fixed memory and removable memory. The data processors may be of any type suitable to the local technical environment, and may include one or more of general purpose computers, special purpose computers, microprocessors, digital signal processors (DSPs), application specific integrated circuits (ASIC), gate level circuits and processors based on multi-core processor architecture, as non-limiting examples.

Embodiments of the inventions may be practiced in various components such as integrated circuit modules. The design of integrated circuits is by and large a highly automated process. Complex and powerful software tools are available for converting a logic level design into a semiconductor circuit design ready to be etched and formed on a semiconductor substrate.

Programs, such as those provided by Synopsys, Inc. of Mountain View, Calif. and Cadence Design, of San Jose, Calif. automatically route conductors and locate components on a semiconductor chip using well established rules of design as well as libraries of pre-stored design modules. Once the design for a semiconductor circuit has been completed, the resultant design, in a standardized electronic format (e.g., Opus, GDSII, or the like) may be transmitted to a semiconductor fabrication facility or “fab” for fabrication.

The foregoing description has provided by way of exemplary and non-limiting examples a full and informative description of the exemplary embodiment of this invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention as defined in the appended claims.

1-26. (canceled)

27. Apparatus comprising:
at least one transducer comprising a displacement component that is configured to move upon application of an electrical signal;
a cavity in communication with the at least one transducer; and
at least one thermodynamic member within the cavity configured to readily exchange heat with a cavity gas or fluid, wherein the transducer is configured to generate a standing wave within the cavity to transfer heat along the thermodynamic member.

28. The apparatus as claimed in claim 27, wherein the thermodynamic member comprises a substrate.

29. The apparatus as claimed in claim 28, wherein the substrate comprises at least one of:
at least two layers of thermodynamic material; and
at least two tubes of the thermodynamic material.

30. The apparatus as claimed in claim 27, wherein the cavity is substantially sealed at at least one end.

31. The apparatus as claimed in claim 27, further comprising a heat sink configured coupled to a first end of the at least one thermodynamic member.

32. The apparatus as claimed in claim 31, wherein the heat sink comprises at least one of:
a cover region of the apparatus; and
a battery of the apparatus.

33. The apparatus as claimed in claim 31, further comprising a first heat conductor coupling the first end of the at least one thermodynamic member to the heat sink at a higher pressure region of the cavity.

34. The apparatus as claimed in claim 31 further comprising a heat source configured to be coupled to a second end of the at least one thermodynamic member.

35. The apparatus as claimed in claim 34, wherein the heat source comprises at least one of:
a processor;
a radio frequency engine;
a baseband engine; and
a projector light source.

36. The apparatus as claimed in claim 34, further comprising a second heat conductor configured to be coupled to the second end of the at least one thermodynamic member of the heat source at a lower pressure region of the cavity.

37. The apparatus as claimed in claim 27, wherein the cavity is a resonator.

38. The apparatus as claimed in claim 37, wherein a first transducer is located at one end of the resonator and the opposite end of the resonator is sealed.

39. The apparatus as claimed in claim 37, wherein a first transducer is located at one end of the resonator and a second transducer is located at the opposite end of the resonator.

40. The apparatus as claimed in claim 27, wherein the at least one thermodynamic member is a material comprising a high heat capacity and a low thermal conductivity.

41. The apparatus as claimed in claim 27, wherein the at least one transducer is further configured to generate an acoustic wave at an audible frequency.

42. A method comprising:
controlling at least one transducer comprising a displacement component to move upon application of an electrical signal;
coupling a cavity with the at least one transducer; and
locating at least one thermodynamic member within the cavity, wherein the at least one thermodymamic member exchanges heat with a cavity gas or fluid;
wherein controlling the at least one transducer generates a standing wave within the cavity and transfers heat along the thermodynamic member.

43. The method as claimed in claim 42 further comprising substantially sealing the cavity at at least one end.

44. The method as claimed in claim 43, further comprising coupling a first heat conductor to a first end of the at least one thermodynamic member at a higher pressure region of the cavity.

45. The method as claimed in claim 44, further comprising coupling a heat source to a second end of the at least one thermodynamic member.

46. The method as claimed in claim 45, wherein coupling a heat source to a second end of the at least one thermodynamic member further comprises coupling a second heat conductor to the second end of the at least one thermodynamic member of the heat source at a lower pressure region of the cavity.
